(19) United States
(12) Patent Application Publication
(10) Pub. No.: US 2011/0242745 A1
(43) Pub. Date: Oct. 6, 2011

(54) ROTARY APPARATUS AND PORTABLE ELECTRONIC DEVICE

(75) Inventor: Kazunori Kono, Kanagawa (JP)

(73) Assignee: PANASONIC CORPORATION, Osaka (JP)

(21) Appl. No.: 13/133,879

(22) PCT Filed: Jun. 8, 2009
(86) PCT No.: PCT/JP2009/002580

§ 371 Date: Jun. 9, 2011

(30) Foreign Application Priority Data
Dec. 10, 2008 (JP) 2008-314445
Dec. 10, 2008 (JP) 2008-314446

(51) Int. Cl. H05K 5/00; E05D 11/10

(52) U.S. Cl. 361/679.01; 16/348; 16/327

(57) ABSTRACT

There is provided a rotary apparatus and a portable electronic device that can be miniaturized. A rotary apparatus 45 includes a first member 51 having a first sleeve 68 and a second sleeve 69; a second member 52 having a shaft member 87 that can rotate axially with respect to the first sleeve and the second sleeve; an annular member 53 that rotates with the shaft member; a biasing member 54 that biases an annular end face 53b of the annular member 53 toward a first end face 68a of the first sleeve; a relative angle maintenance unit 55 that maintains a relative position between the first sleeve and the shaft member at a predetermined angle by engagement of a projection 57 of the annular member with recesses 75 and 76 of the first sleeve; and insertion maintenance unit 56 that maintains the inserted condition of the shaft member with respect to the first sleeve and the second sleeve.

### TECHNICAL FIELD

The present invention relates to a rotary apparatus used as a joint of a portable electronic device in which a first housing provided with an operation section and a second housing provided with a display section are openable and closable coupled together by way of the joint, as well as to a portable electronic device.

### BACKGROUND ART

A hitherto known portable flip type electronic device includes a first housing primarily having an operation section and a second housing primarily having a display section, such as a liquid-crystal screen, and the first housing and the second housing are openable and closable by way of a hinge mechanism (see; for instance, Patent Document 1).

Transmitting/receiving an email, playing a game, and receiving a television broadcast have recently been practiced through use of a display section and an operation section of such a portable electronic device. As a mode of use of such a portable electronic device becomes diversified, so-called vertical-oriented opening has become more convenient when a user makes a call conversation, transmits or receives an email, or plays a game. Specifically, a lower housing (a first housing) and an upper housing (a second housing) are opened in a longitudinal direction by way of a joint (a hinge mechanism), to thus bring the display section and the operation section in vertical orientation so that the user can perform operation in one hand while viewing a box-shaped display section in the vertical orientation. In the meantime, when the user plays a game, performs browsing, or receives a television broadcast, so-called horizontal-oriented opening is convenient. Specifically, the first housing and the second housing are opened in a widthwise direction (a lateral direction) in such a way that the display section is used in horizontal orientation.

For these reasons, the portable terminal that is the portable electronic device described in connection with Patent Document 1 can be switched, by way of the joint (the hinge mechanism), between a vertical open state in which the first housing and the second housing are opened in the longitudinal direction and a horizontal open state in which the first and second housings are opened in the lateral direction.

A common joint has a sleeve fastened to one housing and a shaft member that is inserted into the sleeve and fastened to the other housing. The sleeve and the shaft member are relatively rotated around an axial line of the shaft member, whereby the respective housings are relatively rotated between a closed state and an open state of the portable electronic device.

### RELATED ART DOCUMENT

### Patent Document

Patent Document 1: JP-A-2006-22899

### SUMMARY OF INVENTION

### Technical Problem

Incidentally, miniaturization of the joint has recently been sought along with a reduction in size of the portable electronic device. Conceivable measures to meet such a demand are to shorten the entire length (an axial length) of the sleeve.

However, when external forces are exerted on a joint having a related structure having a short sleeve such that an axial line of the sleeve and an axial line of a shaft member become inclined, the sleeve's capacity to bear the shaft member is low, which raises a problem of backlash being likely to occur in the joint. For this reason, there exists a problem of difficulty being encountered in miniaturizing the joint having the related structure.

After the foregoing portable electronic device has entered the horizontal-opened state, the user may turn the second housing around a first joint shaft with respect to the first housing, so that the device may be incompletely opened in vertical orientation. Countermeasures to prevent occurrence of incomplete vertical-oriented opening have been desired.

The present invention has been conceived to solve the drawbacks and aims at providing a rotary apparatus and a portable electronic device that can be miniaturized.

The present invention also aims at providing a rotary apparatus and a portable electronic device that can prevent a second housing from rotating with respect to a first housing around a first rotation shaft while the second housing stays in a horizontal open state after changed from a closed state to the horizontal open state.

### Solution to Problem

A rotary apparatus according to the present invention comprises:

a first member that has a first sleeve and a second sleeve which are spaced apart from each other;

a second member that has a shaft member which is inserted into both the first sleeve and the second sleeve and which is adapted to rotate axially with respect to the first sleeve and the second sleeve;

an annular member that faces a first end face of the first sleeve oriented to the second sleeve and that rotates with the shaft member;

a biasing member into which the shaft member is inserted at a position between the second sleeve and the annular member, and that biases the annular member toward the first end face of the first sleeve;

a relative angle maintenance unit that has a projection provided on one of the first sleeve and the annular member so as to project toward the other of the first sleeve and the annular member and a recess which is provided on the other of the first sleeve and the annular member to be engaged with the projection and that maintains the first sleeve and the shaft member at a predetermined angle by engagement of the projection with the recess; and

an insertion maintenance unit that maintains the inserted condition of the shaft member with respect to the first sleeve and the second sleeve.

The essential requirement for the first member is that the first member is structured so as to fix a relative position between the first sleeve and the second sleeve; namely, to fix a distance between the first sleeve and the second sleeve. The first sleeve and the second sleeve can also be formed as one unit or separate members.

A structure that can be exemplified as the relative angle maintenance unit includes; for instance, an end face cam. Specifically, a projection projects from an end face of an annular member toward the first sleeve, and a recess capable of engaging with the projection is formed on an end face of the first sleeve. Another additional structure that may also be adopted is; for instance, a circumferential cam. Specifically, an angle slit is formed on a peripheral surface of the first sleeve, and a pin that comes into engagement with the slit is provided on the annular member.

A structure that can be exemplified as the insertion maintenance unit includes bringing the C ring member into engagement with the circumferential slit formed on the peripheral surface of the shaft member. However, the essential requirement for the insertion maintenance unit is to be able to maintain the shaft member so as not to come off from the first sleeve and the second sleeve. The present invention can also adopt; for instance, a structure that brings the C ring member, a split pin, or the like, into engagement with the end of the shaft member.

In the rotary apparatus of the present invention, such as that mentioned above, the first sleeve and the second sleeve are spaced apart from each other. Hence, it becomes possible to make the distance between the most distal ends of the first and second sleeves greater than a sum of the entire length of the first sleeve and the entire length of the second sleeve.

Specifically, in the rotary apparatus of the present invention, even when external forces are exerted on the rotary apparatus such that an axial line of the first sleeve, an axial line of the second sleeve, and an axial line of the shaft member cause respective inclinations, the inclinations existing among the axial line of the first sleeve, the axial line of the second sleeve, and the axial line of the shaft member can be made smaller when compared with a case where there is adopted one sleeve whose entire length is equal to a sum of the entire length of the first sleeve and the entire length of the second sleeve. Rattles, or the like, can thereby be made difficult to occur.

Moreover, when the rotary apparatus of the present invention can allow occurrence of rattlers equivalent to those occurred in the related rotary apparatus, it is possible to make the thickness and entire length of either or both of the first sleeve and the second sleeve small than the thickness and entire length of their counterparts in the related rotary apparatus. Consequently, the entire shape of the rotary apparatus can be made smaller.

Furthermore, in the rotary apparatus of the present invention, the annular member that rotates in synchronism with the shaft member is provided with the projection or recess of the relative angle maintenance unit. Hence, even the shaft member rotates through any angle with respect to the first sleeve as a result of the position of the projection and the position of the recess being selected as required, a resultant relative state can be retained.

Accordingly, when the rotary apparatus of the present invention is used as a joint of a portable electronic device, the first member is secured to the first housing of the portable electronic device, and the second member is secured to the second housing of the same. Further, so long as settings are previously made in such a way that the projection come into engagement with the recess when the portable electronic device is in a closed state and an open state, when the portable electronic device shifts from the closed state to the open state or when the portable electronic device shifts from the open state to the closed state, the projection come into engagement with the recess or the projection come out of engagement of the recess, whereby the user can be given a clear click feeling. The user thereby comes to feel superior usage sense.

In particular, so long as the degree of biasing pressure applied by the biasing member and the depth of engagement of the recess and the projection are selected as required, it is possible to arbitrarily set the intensity or hardness of the click feeling of the rotary apparatus of the present invention. Further, even when the portable electronic device is situated at a position between the closed state and the open state, the projection make sliding contact with respect to the end face of the first sleeve; hence, given rotation torque is generated.

In the rotary apparatus of the present invention, the insertion maintenance unit has a circumferential slit, which is formed in a circumferential direction at a position on a peripheral surface of the shaft member corresponding to spacing between the second sleeve and the biasing member, and a substantially C-shaped ring member to be engaged with the slit. The rotary apparatus has a structure in which biasing pressure that biases the annular member toward the first end face of the first sleeve comes to a preset value when the ring member engages with the circumferential slit.

In such a rotary apparatus of the present invention, the biasing pressure is set to a preset value by means of the insertion maintenance unit that brings the C ring member into an engagement with the circumferential slit of the shaft member at a position between the second sleeve and the biasing member. Put another way, the biasing pressure does not develop before the C ring member is brought into engagement with the circumferential slit.

Therefore, in relation to the rotary apparatus of the present invention, it becomes possible to easily perform assembly operation for inserting the shaft member into the first sleeve, the second sleeve, the annular member, and the biasing member. Further, it also becomes possible to easily disassemble the rotary apparatus by removing the C ring member from the circumferential slit.

In particular, during disassembly of the rotary apparatus of the present invention, there is no necessity to perform destructive disassembly, which would be performed when a specific part is subjected to; for instance, caulking, welding, bonding, press-fitting, or the like. Therefore, recycle of the respective parts during reassembly becomes possible. Further, separated disposal of the rotary apparatus performed on a per-material basis also becomes possible.

In addition, in the rotary apparatus of the present invention, the C ring member is brought, as the insertion maintenance unit, into engagement with the circumferential slit of the shaft member. Therefore, when compared with; for instance, a case where the C ring member is brought into engagement with the circumferential slit at; for instance, an end of the shaft member, the distance between the most distal ends of the first sleeve and the second sleeve can be made greater. As a result, the advantage of the ability to lessen the inclinations existing among the axial line of the first sleeve, the axial line of the second sleeve, and the axial line of the shaft member is further enhanced.

In the rotary apparatus of the present invention, biasing pressure develops as a result of the C ring member being brought into engagement with the circumferential slit. Hence, biasing pressure can be arbitrarily set by selecting the axial dimension of the C ring member as required. Even after the rotary apparatus has been assembled, biasing pressure can be changed by selective use of the C ring member having a different axial dimension.

The rotary apparatus of the present invention is also configured such that the first sleeve and the second sleeve are formed as one by way of an housing fix portion.

In such a rotary apparatus of the present invention, the first sleeve and the second sleeve are formed as one by way of the housing fix portion. Hence, the distance between the first sleeve and the second sleeve can be retained without fail.

Specifically, in the rotary apparatus of the present invention, the distance between the first sleeve and the second sleeve can be retained so as to be exactly equal to a design value for a long period of time. Therefore, an annular end face of the annular member is forcefully actuated toward the first end face of the first sleeve by dint of desired biasing pressure. Click feeling and torque stemming from rotating action are thereby enhanced, and the thus-enhanced click feeling and the torque are generated for a long period of time. Further, operation accuracy can be made uniform at a high level without involvement of occurrence of an individual difference.

Further, in the rotary apparatus of the present invention, the first sleeve and the second sleeve are formed as one by way of the housing fix portion. Consequently, when the rotary apparatus is used as; for instance, a joint of a portable electronic device, the joint can be built in an easier manner when compared with a case where the first sleeve and the second sleeve are separate members.

The rotary apparatus of the present invention is structured so as to include a rotary regulation unit that has a second sleeve contact surface which is provided on an end of the second sleeve on an opposite side of the first sleeve and which intersects with a circumferential direction of the second sleeve and a shaft member contact surface that is provided on the shaft member and that can make a plane contact with the second sleeve contact surface and that regulates rotation angles of the first and second members around an axial line of the shaft member as a result of the second sleeve contact surface and the shaft member contact surface making a plane contact with each other.

In such a rotary apparatus of the present invention, the second sleeve contact surface and the shaft member contact surface come into plane contact with each other, whereby the rotation angles of the first member and the second member are regulated. Therefore, in other words, the rotary regulation unit is provided around the rotary shaft. Accordingly, rotating action of the rotary shaft can be directly regulated without fail.

The rotary apparatus of the present invention is also configured so as to include a guide slit formed in the second sleeve along its longitudinal direction; and a projecting member that is accommodated in the guide slit and that can project toward the shaft member, wherein the shaft member contact surface that intersects with the circumferential direction of the shaft member can contact the projecting member.

In such a rotary apparatus of the present invention, the projecting member and the shaft member contact surface are brought into contact with each other, thereby regulating relative rotating actions of the first member and the second member around the axial line of the shaft member. For this reason, when the rotary apparatus is adopted as a horizontal-oriented open rotary apparatus in a joint of a portable electronic terminal that can assume; for instance, both a vertical open state and a horizontal open state, the portable electronic device in the vertical open state can be reliably prevented from coming into a horizontal open state, so long as settings are previously made such that the projecting member projects from the second sleeve when the portable electronic device starts shifting from the closed state to the vertical open state.

The rotary apparatus of the present invention is also configured so as to include an elastic member that biases the projecting member toward the shaft member.

In such a rotary apparatus of the present invention, the projecting member projects from the second sleeve by means of the elastic member when required. Therefore, relative rotates of the first member and the second member around the axial line of the shaft member can be reliably regulated.

The rotary apparatus of the present invention is configured such that the projecting member has a sloped contact surface whose leading end assumes a substantially-plate-like shape running in its projecting direction and a radial direction of the second sleeve and whose thickness continually becomes smaller along the projecting direction of the projecting member.

In such a rotary apparatus of the present invention, the sloped contact surface that comes into plane contact with the shaft member contact surface is provided at the leading end of the projecting member. Put another way, when compared with the case where the shaft member contact surface and the sloped contact surface are orthogonal to the circumferential direction of the second sleeve and the shaft member, the shaft member contact surface and the sloped contact surface come into plane contact with each other, whereby the second sleeve and the shaft member are pressed so as to turn relatively to each other in opposite directions along the circumference.

Specifically, in the rotary apparatus of the present invention, not only occurrence of relative rotates between the second sleeve and the shaft member is regulated. The shaft member contact surface and the sloped contact surface come into plane contact with each other as if they were wedged to each other, whereby the relative position between the second sleeve and the shaft member can be retained without involvement of occurrence of rattles therebetween.

Incidentally, in a case where the rotary apparatus of the present invention is adopted as; for instance, a horizontal-oriented open rotary apparatus in a joint of a portable electronic device capable of assuming both a vertical open state and a horizontal open state and where the projecting member is set so as not to project from the second sleeve in the closed state and also set so as to project from the second sleeve when the portable electronic device starts shifting from the closed state to the vertical open state, the following may happen if an upright plane orthogonal to the circumferential direction of the shaft member is formed on the opposite side of the location of the shaft member contact surface.

Specifically, the user is assumed to perform operation departed from the original use mode; namely, operation for rotating the upper housing around the rotary shaft for vertical-oriented opening with respect to the lower housing after having shifted the portable electronic device from the closed state to the horizontal open state, whereby the portable electronic device is brought into an incomplete vertical open state. In such a case, when the portable electronic device starts shifting from the horizontal open state to the incomplete vertical open state, the projecting member projects from the second sleeve.

Accordingly, in such a portable electronic device, the upright surface interferes with the projecting member, so that the second sleeve and the shaft member cannot perform relative rotates. As a result, the portable electronic device may not be able to return from the incomplete vertical open state to the normal vertical open state.

In contrast, the rotary apparatus of the present invention is configured such that the shaft member has a return inclined surface that intersects with the circumferential direction of the shaft member and that is an opposite side of the shaft member contact surface.

In such a rotary apparatus of the present invention, even when the portable electronic device has entered an incomplete vertical open state as mentioned above, the second sleeve and the shaft member can make relative rotates while the projecting member is being pushed into the second sleeve by means of the return inclined surface. Hence, the portable electronic device can return from the incomplete vertical open state to the normal vertical open state.

A rotary apparatus of the present invention also assumes a structure comprising a first member having a sleeve; a second member that is inserted into the sleeve and that has a shaft member capable of making a shaft turn relatively to the sleeve; a guide slit formed in the sleeve along its longitudinal direction; a projecting member that is accommodated in the guide slit and that can project toward the shaft member; and a shaft member contact surface that intersects with a circumferential direction of the shaft member and that can contact the projecting member.

In such a rotary apparatus of the present invention, the projecting member and the shaft member contact surface are brought into contact with each other, thereby regulating relative rotating actions of the first member and the second member around the axial line of the shaft member. For this reason, when the rotary apparatus is adopted as a rotary apparatus for horizontal-oriented opening in a joint of a portable electronic terminal that can assume; for instance, both a vertical open state and a horizontal open state, the portable electronic device in the vertical open state can be reliably prevented from coming into a horizontal open state, so long as settings are previously made such that the projecting member projects from the sleeve when the portable electronic device starts shifting from the closed state to the vertical open state.

The rotary apparatus of the present invention is also configured so as to include an elastic member that biases the projecting member toward the shaft member.

In such a rotary apparatus of the present invention, the projecting member projects from the sleeve by means of the elastic member when required. Therefore, relative rotates of the first member and the second member around the axial line of the shaft member can be reliably regulated.

The rotary apparatus of the present invention is also configured such that the projecting member has a sloped contact surface whose leading end assumes a substantially-plate-like shape running in its projecting direction and also a radial direction of the sleeve and whose thickness becomes continually smaller along the projecting direction.

In such a rotary apparatus of the present invention, the sloped contact surface that comes into plane contact with the shaft member contact surface is provided at the leading end of the projecting member. Put another way, when compared with the case where the shaft member contact surface and the sloped contact surface are orthogonal to the circumferential direction of the sleeve and the shaft member, the shaft member contact surface and the sloped contact surface come into plane contact with each other, whereby the sleeve and the shaft member are pressed so as to turn relatively to each other in opposite directions along the circumference.

Specifically, in the rotary apparatus of the present invention, not only occurrence of relative rotates between the second sleeve and the shaft member is regulated. In addition, the shaft member contact surface and the sloped contact surface come into plane contact with each other as if they were wedged to each other, whereby the relative position between the sleeve and the shaft member can be retained without involvement of rattles therebetween.

Incidentally, in a case where the rotary apparatus of the present invention is adopted as; for instance, a horizontal-oriented open rotary apparatus in a joint of a portable electronic device capable of assuming both a vertical open state and a horizontal open state and where the projecting member is set so as not to project from the sleeve in the closed state and also set so as to project from the sleeve when the portable electronic device starts shifting from the closed state to the vertical open state, the following may happen if an upright plane orthogonal to the circumferential direction of the shaft member is formed on the opposite side of the location of the shaft member contact surface.

Specifically, the user is assumed to perform operation departed from the original use mode; namely, operation for rotating the upper housing around the rotary shaft for vertical-oriented opening with respect to the lower housing after having shifted the portable electronic device from the closed state to the vertical open state, whereby the portable terminal is brought into an incomplete horizontal open state. In such a case, when the portable electronic device starts shifting from the horizontal open state to the incomplete vertical open state, the projecting member projects from the sleeve.

Accordingly, in such a portable electronic device, the upright surface interferes with the projecting member, so that the sleeve and the shaft member cannot perform relative rotates. As a result, the portable electronic device may not be able to return from the incomplete vertical open state to the normal vertical open state.

In contrast, the rotary apparatus of the present invention is configured so as to include a return inclined surface that intersects with the circumferential direction of the shaft member and that is an opposite side of the shaft member contact surface.

In such a rotary apparatus of the present invention, even when the portable electronic device has entered an incomplete vertical open state as mentioned above, the sleeve and the shaft member can make relative rotates while the projecting member is being pushed into the sleeve by means of the return inclined surface. Hence, the portable electronic device can return from the incomplete vertical open state to the normal vertical open state.

Now, a portable electronic device of the present invention includes a first housing having an operation section; a second housing having a display section; a joint housing for joining the first housing and the second housing together; an operation surface provided with the operation section in order to join the first housing to the joint housing; a first joint shaft interposed between the operation surface and a surface of the first housing on the other side of the operation surface; and a second joint shaft disposed for joining the second housing and the joint housing together, wherein a surface of the joint housing continually lies in level with the operation surface of the first housing and also opposes a display surface in which the display section of the second housing is provided when the first housing and the second housing are piled one on top of the other in a closed manner; wherein, in a vertical open state where the first housing and the second housing perform relative rotations around the first joint shaft from the closed state, the joint housing makes a turn with the surface of the joint housing opposing the display surface of the second housing, and the surface of the joint housing and the operation surface are oriented in mutually different directions; wherein, in a horizontal open state where the first housing and the second housing perform relative rotations around the second joint shaft from the closed state, the surface of the joint housing continually lies in level with the operation surface of the first housing, and the surface of the joint housing and the display surface of the second housing are oriented in mutually-different directions; wherein the second joint shaft is equipped with the previously-described rotary apparatus; wherein the first member of the rotary apparatus is secured to the joint housing; wherein the second member of the rotary apparatus is secured to the second housing; and wherein the first housing is provided with a lock section for controlling engagement of the projecting member with the shaft member.

### Advantages of the Invention

According to the rotary apparatus and the portable electronic device of the present invention, there is yielded an advantage of the ability to miniaturize the rotary apparatus and the portable electronic device.

According to the rotary apparatus and the portable electronic device of the present invention, there is yielded an advantage of the ability to prevent rotating of the second housing with respect to the first housing around the first rotary shaft while the second housing stays in a horizontal open state after changed from a closed state to the horizontal open state.

### BRIEF DESCRIPTION OF THE DRAWINGS

FIG. 1 It is an oblique perspective view showing a horizontal open state of a portable terminal of a first embodiment of the present invention.

FIG. 2 It is an oblique perspective view showing a vertical open state of the portable terminal of the first embodiment of the present invention.

FIG. 3 It is an oblique perspective view showing a closed state of the portable terminal of the first embodiment of the present invention.

FIG. 4 It is an exploded view of the portable terminal of the first embodiment of the present invention.

FIG. 5 It is an exploded perspective view of a joint.

FIG. 6 It is an exploded perspective view of a rotary apparatus.

FIG. 7 It is a cross sectional view of the rotary apparatus.

FIG. 8 It is a view showing a shaft member contact surface and a projecting member.

FIG. 9 It is a view for explaining a relationship among the shaft member contact surface, the projecting member, the projections, and first recesses achieved when the portable terminal is closed.

FIG. 10 It is a view for explaining a relationship among the shaft member contact surface, the projecting member, projections, and the first recesses achieved when the portable terminal is in a horizontal open state.

FIG. 11 It is an exploded perspective view showing a first engagement section and a second engagement section.

FIG. 12 It is a drawing of the principle showing a reason for separation of a first sleeve from a second sleeve.

FIG. 13 It is an oblique perspective view for describing function of a return inclined surface.

FIG. 14 It is a cross sectional view showing a biasing member of a second embodiment of the present invention.

FIG. 15 It is a cross sectional view sowing an annular member and a C ring member of a third embodiment of the present invention.

### EMBODIMENTS FOR IMPLEMENTING THE INVENTION

A portable electronic device of an embodiment of the present invention is hereunder described by reference to the drawings.

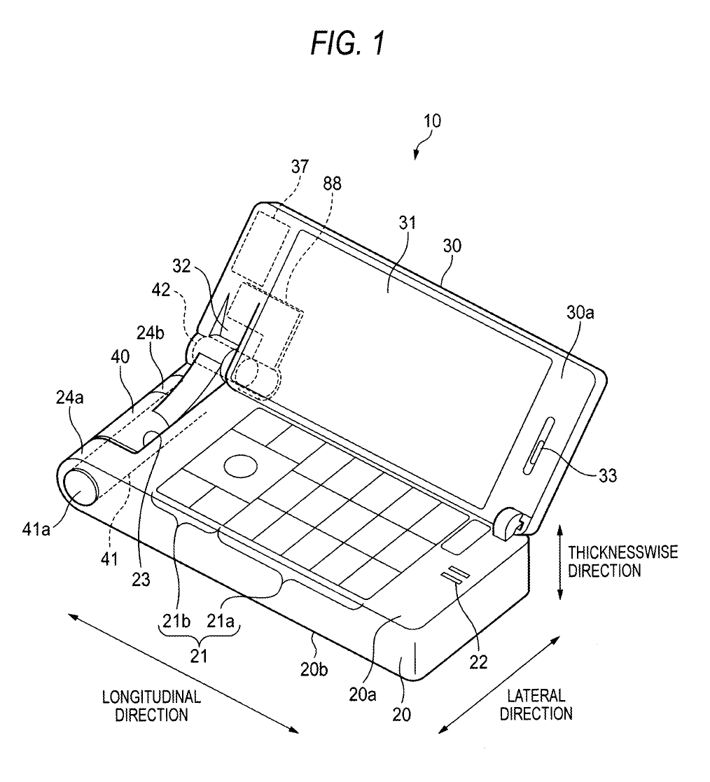

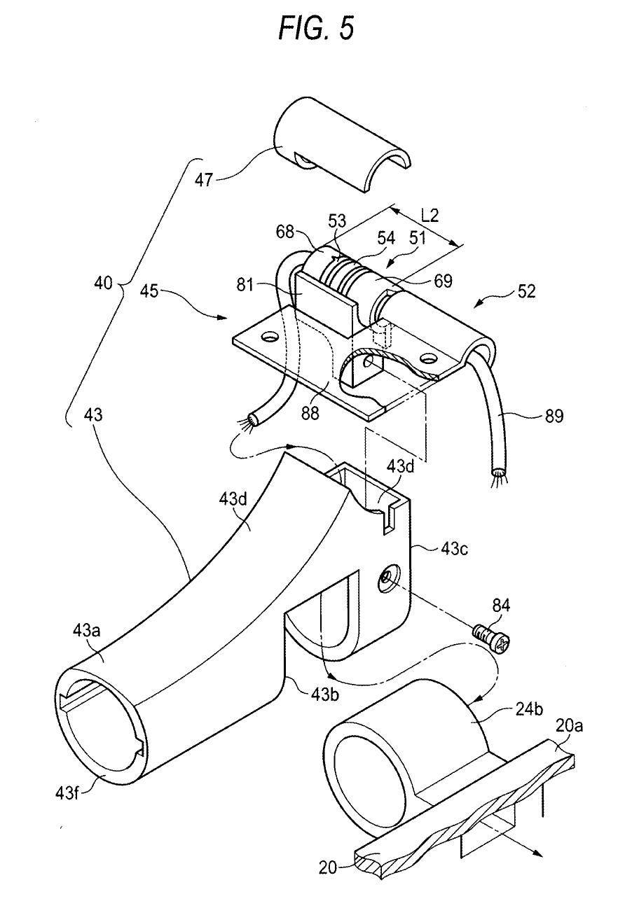

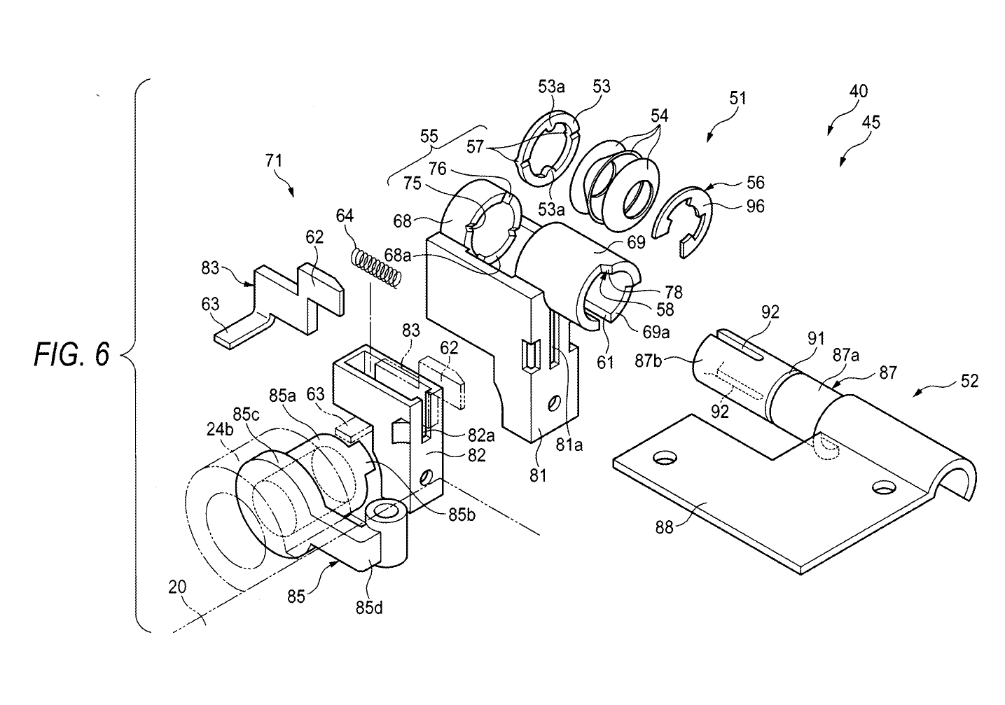

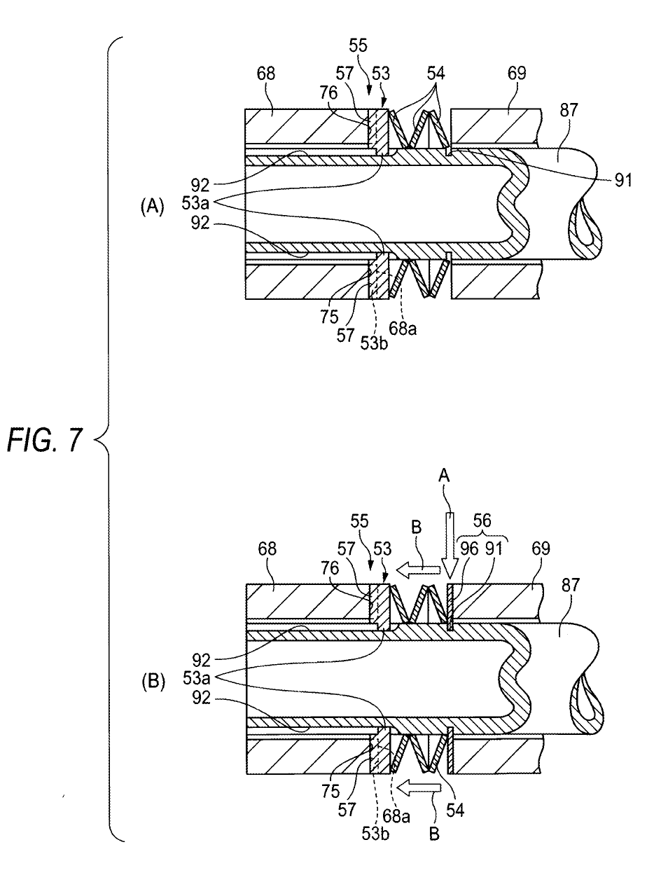

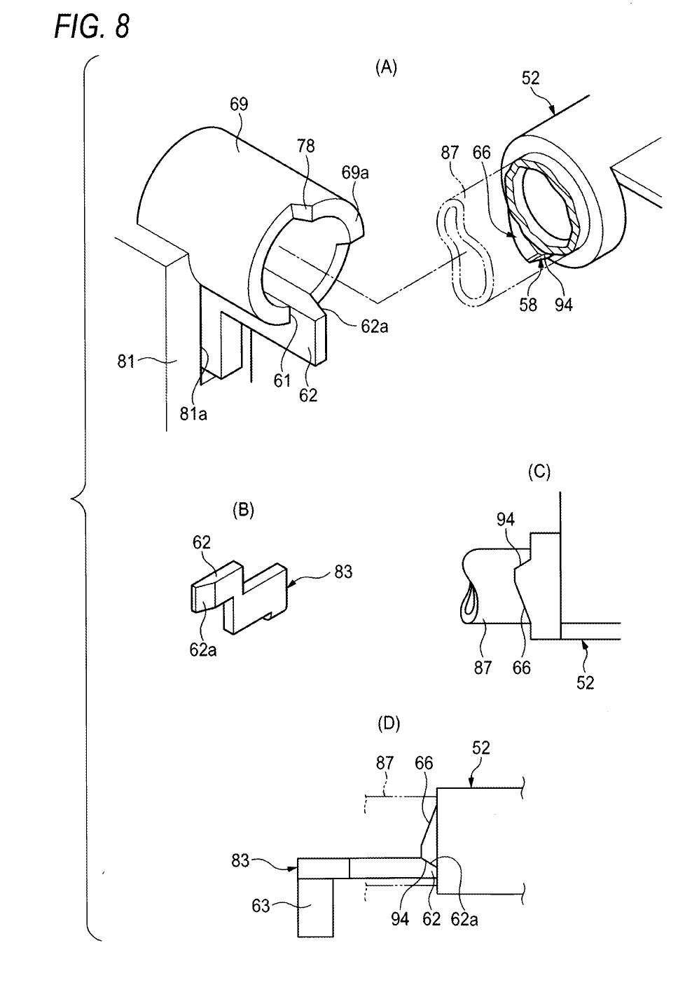

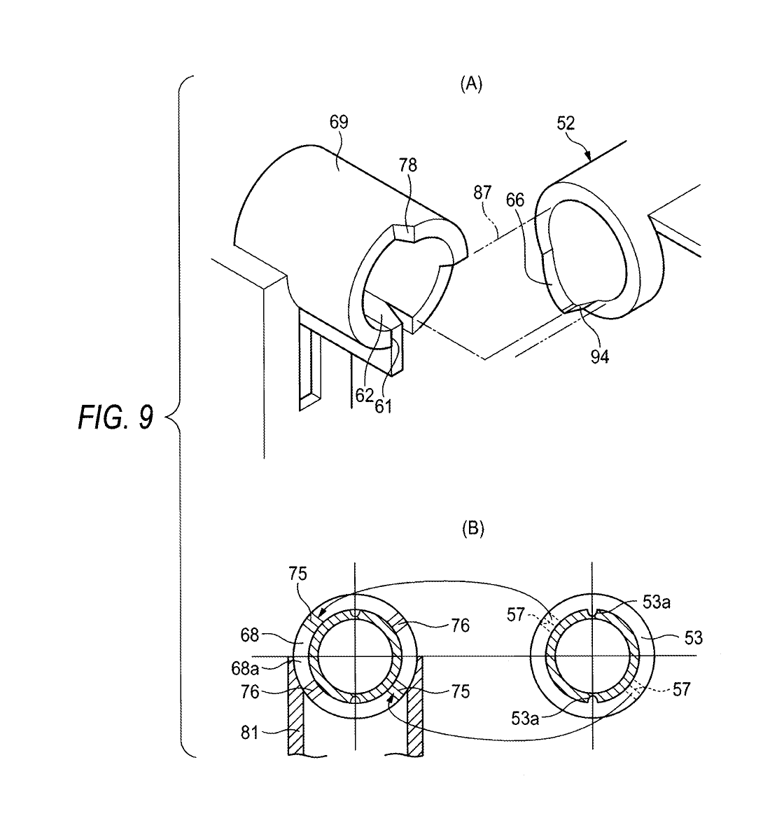

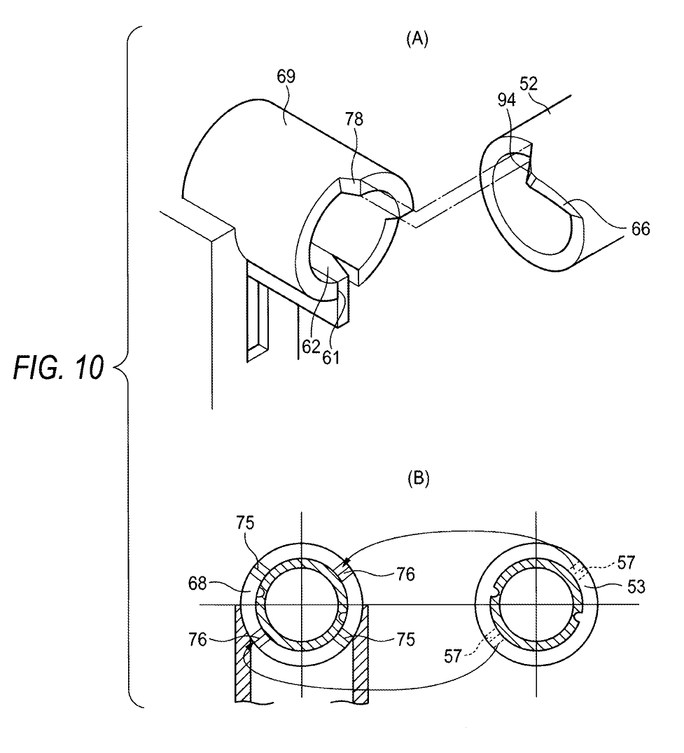

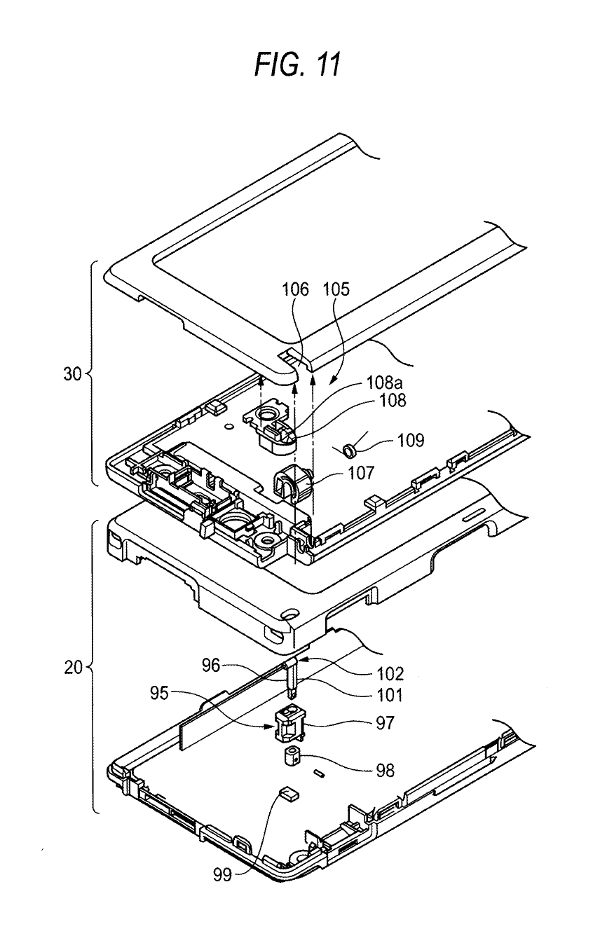

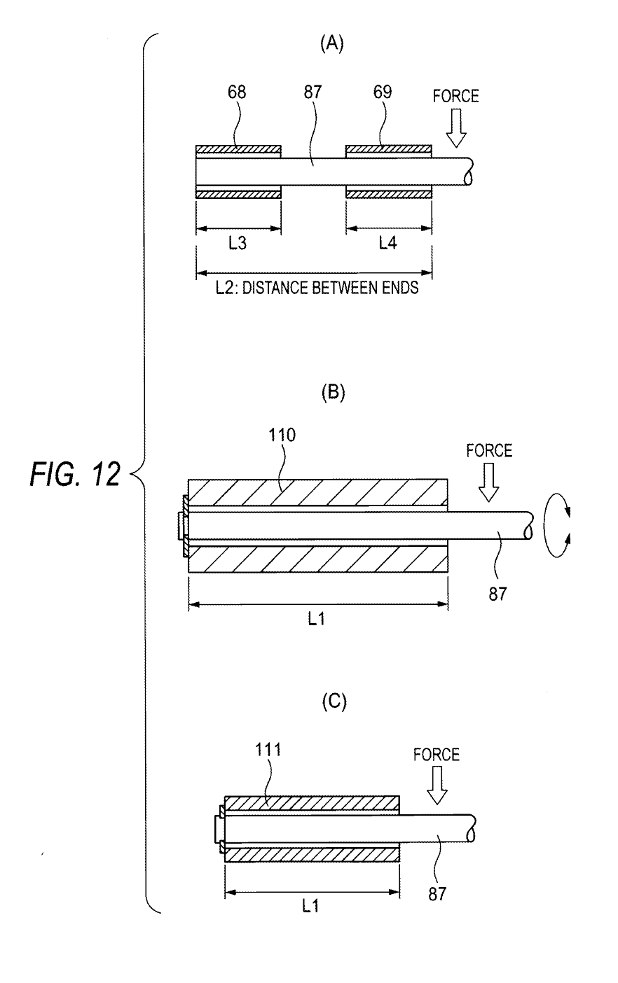

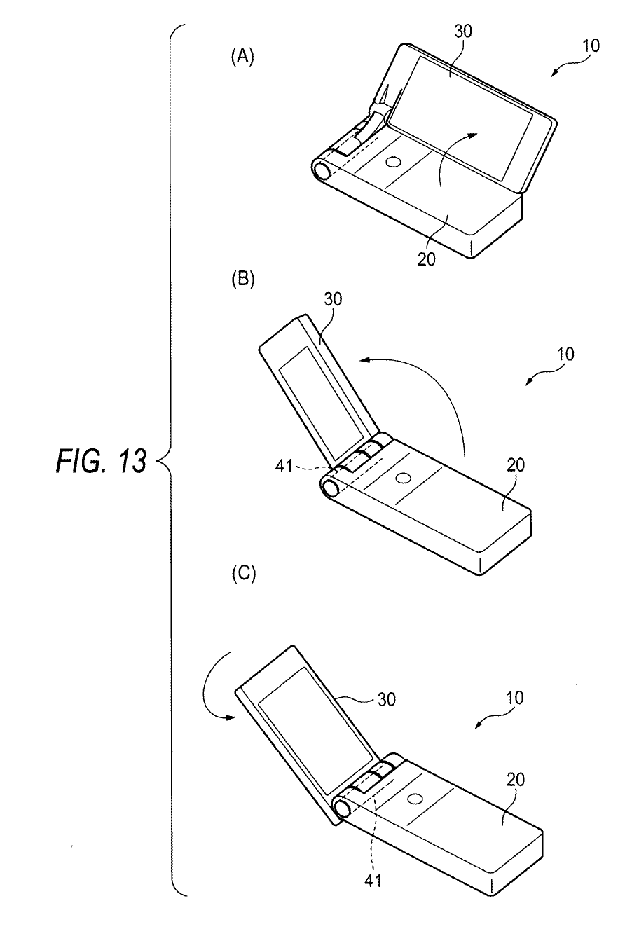

FIGS. 1 through 4 are drawings showing a portable terminal that is a portable electronic terminal of a first embodiment of the present invention. FIG. 5 is an exploded perspective view of a joint; FIG. 6 is an exploded perspective view of a rotary apparatus; FIG. 7 is a cross sectional view of the rotary apparatus; FIG. 8 is a view showing a shaft member contact surface and a projecting member; FIG. 9 is a view for explaining a relationship among the shaft member contact surface, the projecting member, projections 57, and first recesses achieved when the portable terminal is closed; FIG. 10 is a view for explaining a relationship among the shaft member contact surface, the projecting member, the projections 57, and the first recesses achieved when the portable terminal is in a horizontal open state; FIG. 11 is an exploded perspective view showing a first engagement section and a second engagement section; FIG. 12 is a drawing of the principle showing a reason for separation of a first sleeve from a second sleeve; and FIG. 13 is an oblique perspective view for describing function of a return inclined surface.

### First Embodiment

FIGS. 1 through 3 show the first embodiment of the present invention. A portable terminal 10 serving as the portable electronic terminal of the first embodiment includes a rectangular-box-shaped first housing 20, a rectangular-box-shaped second housing 30, and a joint 40 that joins the first housing 20 to the second housing 30.

In the portable terminal 10, the first housing 20 and the joint 40 are joined together by way of a first rotary shaft 41, and the second housing 30 and the joint 40 are joined together by way of a second rotary shaft 42.

In the first embodiment provided below, a direction running along the direction in which the first housing 20 and the joint 40 are arranged is called a longitudinal direction, and a direction orthogonal to the longitudinal direction is called a lateral direction. In addition, a direction orthogonal to both the longitudinal direction and the lateral direction is called a thicknesswise direction of the first housing 20.

A longitudinal direction, a lateral direction, and a thicknesswise direction of the second housing 30 are called in the same manner as the longitudinal direction, the lateral direction, and the thicknesswise direction of the first housing 20.

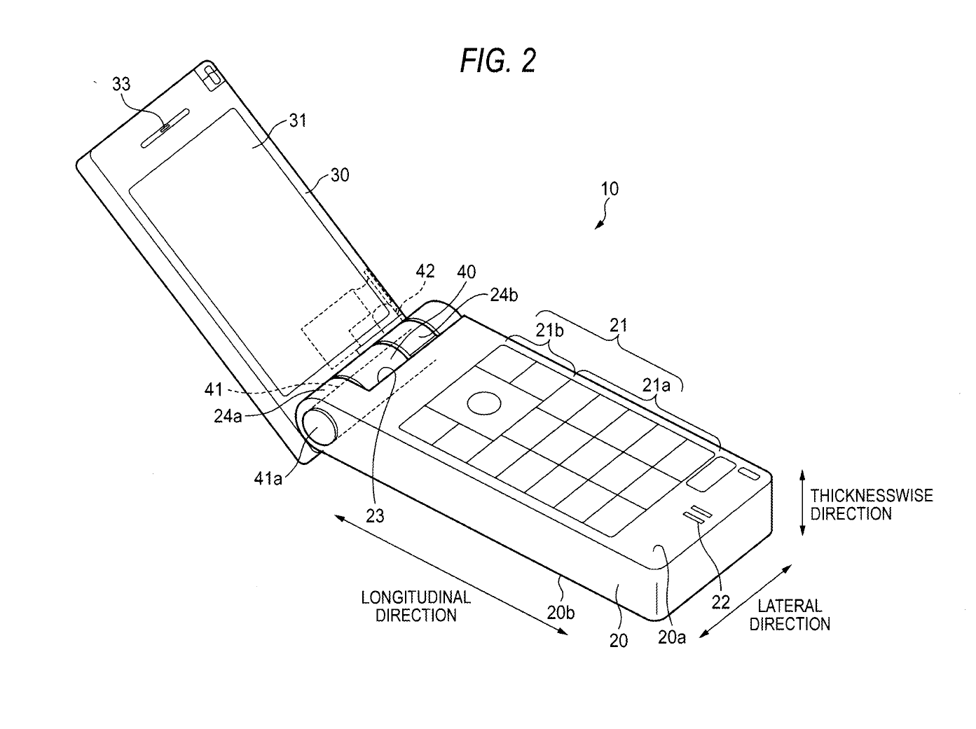

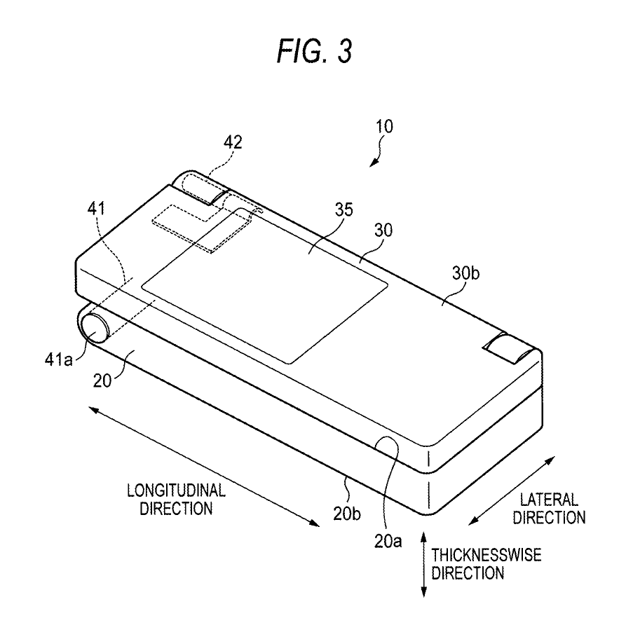

Moreover, the portable terminal 10 can assume all of three states: namely, a closed state (a state shown in FIG. 3) in which the first housing 20 and the second housing 30 are relatively stacked one on top of the other; a vertical open state (a state shown in FIG. 2) in which the second housing 30 and the joint 40 are rotated as one from the closed state around the first rotary shaft 41 with respect to the first housing 20; and a horizontal open state (a state shown in FIG. 1) in which the second housing 30 is rotated from the closed state around the second rotary shaft 42 with respect to the first housing 20.

The first housing 20 is an element that is griped with one hand or both hands when the user uses the portable terminal 10. An operation section 21 including a group of input keys 21a used for inputting numerals and characters and a group of function keys 21b used for making various settings and switching functions is provided in an operation surface 20a.

A pair of first housing supports 24a and 24b are provided at one end of the first housing 20 in its longitudinal direction (i.e., an end positioned in the proximity of the group of function keys 21b). A microphone 22 is provided on the operation surface 20a and at the other end of the first housing 20 in the longitudinal direction.

The microphone 22 is for collecting user's voice when the portable terminal 10 is opened in vertical orientation so that it can be used as a phone.

The first housing supports 24a and 24b project from a lateral end face of the first housing 20 in the longitudinal direction, and are spaced apart, at a predetermined distance, from each other along the lateral direction of the first housing 20 by way of a cutout 23. The first housing support 24a is arranged in such a way that end faces of the support assuming a substantially-U-shaped profile continually lead to a side end face of the first housing 20. The first housing support 24b is arranged in such a way that end faces of the support assuming a substantially-U-shaped profile makes a step with respect to the side end face of the first housing 20.

The first housing supports 24a and 24b do not project from the operation surface 20a of the first housing 20 nor an exterior surface 20b on the opposite side of the operation surface 20a.

An operation button 41a for one push opener that is a mechanism for bringing the portable terminal 10 in a closed state into a vertical open state is provided on an end face of the first housing support 24a.

The one push opener is a mechanism for releasing a built-in spring (not shown) bridged between the first housing 20 and the joint 40 from a compressed state into a stretched state, thereby bringing the portable terminal 10 into a vertical open state.

In the first housing 20, the first rotary shaft 41 is supported by the first housing supports 24a and 24b. Therefore, in other words, while staying between the operation surface 20a and the exterior surface 20b on the opposite side thereof, the first rotary shaft 41 lies in parallel to the operation surface 20a and is also aligned to the lateral direction orthogonal to the longitudinal direction along which the first housing 20 and the joint 40 are arranged.

Therefore, the first housing 20 obviates a necessity to provide the operation surface 20a with a projection used for accommodating the first rotary shaft 41, and the operation surface 20a is formed flat.

The second housing 30 is equipped with a main display section 31, like an LCD, provided on a display surface 30a opposing the operation surface 20a of the first housing 20 in the closed state (the state shown in FIG. 3). Further, a sub-display section 35 is provided on an exterior surface 30b on the opposite side of the display surface 30a.

The main display section 31 is used, in both the vertical open state and the horizontal open state, as a screen for displaying a game or a TV broadcast.

A sound emitter section 33 is provided at one end of the display surface 30a of the second housing 30 in its longitudinal direction, in order to generate a transmitted speech, and the like, when brought into contact with a user's ear during the course of the portable terminal being used in vertical orientation as a phone. Further, an indentation 32 and an antenna 37 (see FIG. 1) are provided on the other end (an end located in the proximity of the joint 40) of the second housing in its longitudinal direction.

The antenna 37 is accommodated in the second housing 30.

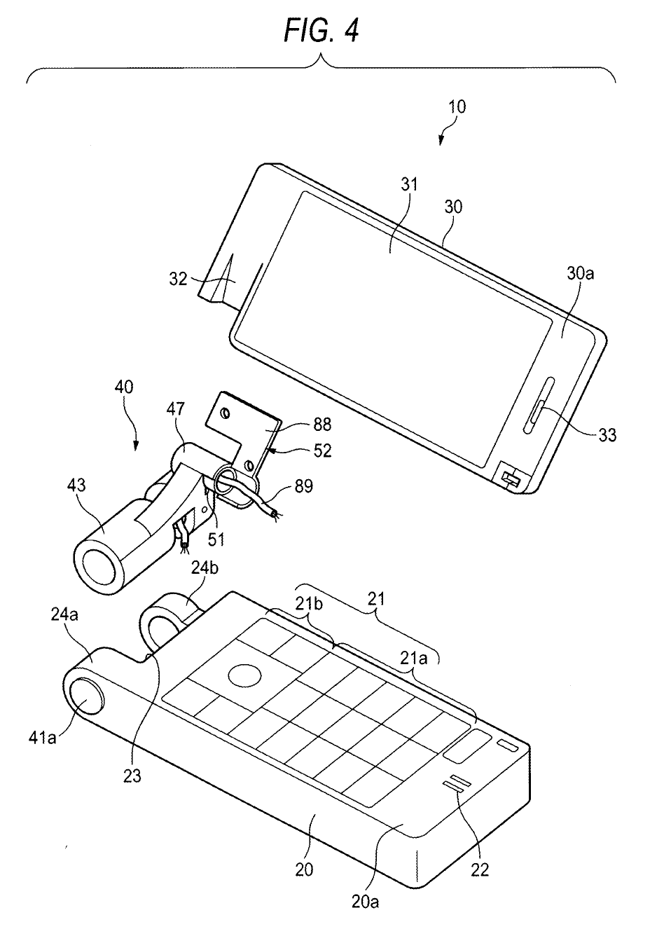

As shown in FIGS. 4 and 5, the joint 40 has a substantially tubular joint body 43 inserted into the first rotary shaft 41, a rotary apparatus 45 supported by the joint body 43, and a joint cover member 47 covering the rotary apparatus 45.

The joint body 43, assuming a substantially cylindrical shape, includes as a portion thereof a surface 43a that will continually lead to the operation surface 20a of the first housing 20 in the vertical open state and the horizontal open state of the portable terminal 10, without involvement of occurrence of a step and a cutout 43b provided on the opposite side of the surface 43a.

The joint body 43 has a slope 43d that extends from the surface 43a to one end 43c (a distal end in FIG. 5) and the cutout 43d formed in an area of the end 43c so as to establish mutual communication between the inside and outside of the joint body.

The joint body 43 is axially inserted into the first rotary shaft 41 such that a remaining end 43f (a proximal end in FIG. 5) comes into contact with the first housing support 24a (see FIG. 4); that the first housing support 24b is accommodated in the cutout 43b; and that the end 43c remains continual to a side end face of the first housing 20 (see FIG. 1).

Accordingly, the joint body 43 is rotatable around the axial line of the first rotary shaft 41 with respect to the first housing 20.

A shape and a diameter of the joint body 43 are set in such a way that the joint body does not project from the operation surface 20a of the first housing 20 when the portable terminal 10 is held in the vertical open state or the horizontal open state.

Example surface profiles of the surface 43a commensurate with a surface profile of the operation surface 20a include; for instance, a flat surface, a circular-arc surface, and a curved surface. An additional display section, an operation button, or the like, can also be placed on the surface 43a.

As shown in FIGS. 5 and 6, the rotary apparatus 45 includes a first member 51 secured to the joint body 43 of the joint 40 with a screw 84; a second member 52 that is secured to the second housing 30 (see FIG. 1) and joined to the first member 51; an annular member 53 that rotates in synchronism with a second joint shaft 87 that is a rotary shaft provided in the second member 52; a biasing member 54 that biases the annular member 53; a relative angle maintenance unit 55 that retains a relative position between the first member 51 and the second member 52 at a predetermined angle; and insertion maintenance unit 56 that retains the second member 52 joined to the first member 51.

The rotary apparatus 45 includes rotary regulation unit 58 for regulating a rotation angle of the first member 51 and a rotation angle of the second member 52 around an axial line of the second joint shaft 87; a guide slit 61 formed in the first member 51; a projecting member 62 that is accommodated in the guide slit 61 and that can project toward the second member 52; and an elastic member 64 that biases the projecting member 62 toward the second member 52.

The first member 51 includes a first sleeve 68 and a second sleeve 69 spaced, in line with, apart from each other.

The first sleeve 68 and the second sleeve 69 are formed in one by way of an housing fix portion 71. The housing fix portion 71 is secured to an interior of an external end of the joint body 43 (see FIG. 5) with the screw 84.

So long as the first member 51 has a structure in which a relative position between the first sleeve 68 and the second sleeve 69 is not changed by the biasing member 54 (biasing member), the first sleeve 68 and the second sleeve 69 may be embodied as separate members.

The first sleeve 68 is formed such that the shaft member 87 of the second member 52 can be inserted into the first sleeve. A first recess 75 and a second recess 76 are formed in a first end face 68a.

The first recess 75 and the second recess 76 pair up with each other and are formed in the first end face 68a while being spaced apart from each other with respect to the axial line of the first sleeve 68 and in the neighborhood of; for instance, an angle of 120 degrees (see also FIGS. 9 and 10).

The second sleeve 69 is formed such that the shaft member 87 of the second member 52 can be inserted into the second sleeve. A second sleeve contact surface 78 is provided on an end 69a on the opposite side of the first sleeve 68. The guide slit 61 runs along a generatrix of the second sleeve 69 (i.e., the longitudinal direction).

In the housing fix portion 71, an internal member 82 is accommodated in an external member 81 such that an external window 81a of the external member 81 coincides with an internal window 82a of the internal member 82. A slide member 83 and the elastic member 64 are placed in the internal member 82.

In the housing fix portion 71, an upper end of the external window 81a and an upper end of the internal window 82a are in mutual communication with the guide slit 61.

The slide member 83 is slidably actuated along the external window 81a, the internal window 82a, and the guide slit 61 and is kept projecting toward the second member 52 by means of restoring spring force of the elastic member 64.

The projecting member 62 and a regulation arm 63 are provided on the slide member 83.

A small diameter portion 85a and a regulating projection 85b of a hinge guide 85 are provided in an outer end portion of the joint body 43. In the guide hinge 85, a large diameter portion 85c is interposed between the first housing support 24b and the outer end portion of the joint body 43, and a first housing fix portion 85d is secured to the first housing 20.

The regulating projection 85b can contact the regulation arm 63.

The second member 52 includes a second housing fix portion 88 secured to the second housing 30 and the shaft member 87 provided in the second housing fix portion 88.

The shaft member 87 is a member that is inserted into the first sleeve 68 and the second sleeve 69 and that can axially turn relatively to the first sleeve 68 and the second sleeve 69.

The shaft member 87 is hollowly formed so as to enable insertion of a wire harness 89. A circumferential slit 91 and a pair of detent slit 92 are formed in a peripheral surface 87a. In addition, a shaft member contact surface 94 [see FIG. 8(A)] capable of making a plane contact with the second sleeve contact surface 78 is formed on the peripheral surface 87a.

The annular member 53 is formed such that it can be inserted into the shaft member 87 at a position between the first sleeve 68 and the second sleeve 69 while facing the first end face 68a of the first sleeve 68 oriented toward the second sleeve 69.

As shown in FIG. 7(A), a pair of detent projections 53a are formed on an inner periphery of the annular member 53, and a pair of projections 57 are formed on an annular end face 53b opposing the first end face 68a.

The rotation stop projections 53a fit to the pair of corresponding detent slits 92, whereby the annular member 53 can be rotated in synchronism with the shaft member 87.

The biasing member 54 corresponds to a plurality of disc springs that are inserted into the shaft member 87 at a position between the second sleeve 69 and the annular member 53 and that forcefully actuate the annular end face 53b of the annular member 53 toward the first end face 68a of the first sleeve 68.

Although the first embodiment exemplifies disc springs as the biasing member, a coil spring, a bamboo spring, a wave washer, and the like, can also be adopted as the example biasing member of the present invention.

The relative angle maintenance unit 55 includes the pair of projections 57 that are provided on the annular end face 53b of the annular member 53 and that project toward the first end face 68a of the first sleeve 68, as well as including the first recesses 75 and the second recesses 76 that are engaged with the pair of projections 57 (see also FIG. 6).

The relative angle maintenance unit 55 maintains a relative position between the first sleeve 68 and the shaft member 87 at a predetermined angle with reference to an axial line of the first sleeve 68 and an axial line of the shaft member 87 as a result of the projections 57 being engaged with the first recesses 75 and the second recesses 76.

The insertion maintenance unit 56 shown in FIG. 7(B) maintains the state of the shaft member 87 inserted in the first sleeve 68 and the second sleeve 69.

The insertion maintenance unit 56 has the circumferential slit 91 formed in the peripheral surface 87a of the shaft member 87 and a C ring member (E ring) 96 to be engaged with the circumferential slit 91.

The circumferential slit 91 is formed at a position on the peripheral surface 87a of the shaft member 87 between the second sleeve 69 and the biasing member 54 and along the circumferential direction.

The C ring member 96 is engaged with the circumferential slit 91 at the position between the second sleeve 69 and the biasing member 54 as designated by arrow A, whereby the biasing member 54 is compressed by the C ring member 96 as designated by arrow B.

Biasing pressure of the biasing member 54 that biases the annular end face 53b of the annular member 53 toward the first end face 68a of the first sleeve 68 is thereby set to a preset value.

The first embodiment provides an exemplified structure of the insertion maintenance unit 56 in which the C ring member 96 is engaged with the circumferential slit 91 of the shaft member 87. However, the essential requirement for the insertion maintenance unit is to be able to retain the shaft member 87 in such a way that the shaft member does not come out of the first sleeve 68 and the second sleeve 69. There may also be adopted a structure in which the C ring member, a split pin, or the like, is engaged with; for instance, an end of the shaft member 87.

As shown in FIGS. 8(A) to (C), the rotary regulation unit 58 includes the second sleeve contact surface 78 on the second sleeve 69 and the shaft member contact surface 94 provided on the shaft member 87.

The second sleeve contact surface 7 is provided at the end 69a of the second sleeve 69 on the opposite side of the location of the first sleeve 68, so as to intersect with a circumferential direction of the second sleeve 69.

The shaft member contact surface 94 is a surface capable of making a surface contact with the second sleeve contact surface 78.

The second sleeve contact surface 78 and the shaft member contact surface 94 make up a stopper that regulates a rotation angle of the first member 51 and a rotation angle of the second member 52 (see FIG. 5) around the axial line of the shaft member 87 as a result of both of the contact surfaces contacting each other.

As mentioned previously, the guide slit 61 is a slit formed along the generatrix of the second sleeve 69 (i.e., the longitudinal direction).

The projection member 62 shown in FIG. 8(B) is a member that is accommodated in the guide slit 61 and that can project toward the shaft member 87.

The projecting member 62 has a sloped contact surface 62a whose leading end assumes a substantially plate-like shape running in the radial direction of the second sleeve 69 and whose thicknesswise dimension becomes continually smaller along a projecting direction.

The elastic member 64 (see FIG. 6) is a member that biases the projecting member 62 toward the shaft member 87.

The projecting member 62 is provided in the guide slit 61 so as to be able to project toward the shaft member 87, whereby the shaft member contact surface 94 becomes able to come into plane contact with the projecting member 62.

Turning back to FIG. 6, a relationship between the foregoing regulating arm 63 and the regulating projection 85b is now described.

The regulating arm 63 and the regulating projection 85b are retained in a separated manner in the state of the portable terminal 10 being opened in the vertical orientation.

Therefore, the projecting member 62 projects from the guide slit 61 toward the shaft member 87 by means of the force exerted by the elastic member 64.

In the meantime, in relation to the regulating arm 63 and the regulating projection 85b, the regulating projection 85b pushes, in a closed state of the portable terminal 10, the regulating arm 63 into the first sleeve 68 against the force exerted by the elastic member 64.

Therefore, the projecting member 62 is accommodated in the guide slit 61.

As shown in FIG. 9(A), the projecting member 62 is accommodated in the guide slit 61 in the closed state of the portable terminal 10. The first member 51 and the second member 52 (see FIG. 6) thereby become able to perform relative rotates around the axial line of the shaft member 87, so that the portable terminal 10 can be opened in the horizontal orientation.

As shown in FIG. 9(B), in the closed state of the portable terminal 10, the pair of projections 57 remain engaged with (fitted into) the pair of first recesses 75. Therefore, the portable terminal can be set so as to open in the horizontal orientation only when the pair of projections 57 come out of the pair of first recesses 75 as a result of given force or greater being exerted on the portable terminal.

When opening the portable terminal 10 in the vertical orientation is started, the projecting member 62 projects toward the shaft member 87 from the guide slit 61 by the force exerted by the elastic member 64 as shown in FIG. 8(A).

As shown in FIG. 8(D), the shaft member contact surface 94 thereby comes into plane contact with the projecting member 62 (the sloped contact surface 62a), thereby becoming able to regulate relative rotations of the first member 51 and the second member 52 around the axial line of the shaft member 87.

Accordingly, the portable terminal 10 opened in the vertical orientation can be prevented from opening in the horizontal orientation.

As shown in FIG. 10(A), the shaft member contact surface 94 comes into contact with the second sleeve contact surface 78, whereupon the projecting member 62 is accommodated into the guide slit 61 in the state of the portable terminal 10 remaining opened in the horizontal orientation. The first member 51 and the second member 52 (see FIG. 6) thereby become possible to perform relative rotations around the axial line of the shaft member 87, so that the portable terminal 10 can be closed.

As shown in FIG. 10(B), the pair of projections 57 remain engaged with (fitted into) the pair of second recesses 76 in the closed state of the portable terminal 10. Therefore, the portable terminal can be set so as to close (return to its original state) only when the pair of projections 57 come out of the pair of second recesses 76 as a result of given force or greater being exerted on the portable terminal.

As shown in FIG. 8(A), a return inclined surface 66, provided on the opposite side of the location of the shaft member contact surface 94, crosses the circumferential direction of the shaft member 87.

The reason why the return inclined surface 66 is provided on the opposite side of the location of the shaft member contact surface 94 will be described in detail by reference to FIG. 13.

The joint cover member 47 shown in FIG. 5 is one for covering an upper half of the first member 51, to thus enhance the appearance of the portable terminal 10.

As shown in FIG. 11, a first engagement section 95 provided in the first housing 20 includes an engagement pawl 96, a retainer 97 for retaining the engagement pawl 96, a stopper 98 for preventing the engagement pawl 96 form coming off from the retainer 97, and a first housing magnet 99.

The engagement pawl 96 includes a first projection 101 projecting from the first housing 20 to the second housing 30 and a second projection 102 that is connected to the first projection 101 and that extends in a direction crossing the first projection.

A second engagement section 105 provided in the second housing 30 has an opening 106. The second engagement section further includes a first accommodation section 107 that is provided so as to be rotatable within the opening 106; that accommodates the first projection 101; and that includes an insert molded magnet. The second engagement section additionally includes a second accommodation section 108 that rotates as one with the second housing 30 and that has an opening 108a for accommodating the second projection 102; and a return spring 109 that rotates the second accommodation section 108, thereby aligning an orientation of the opening of the first accommodation section 107 with an orientation of the second accommodation section 108.

Accordingly, in the closed state of the portable terminal 10, the engagement pawl 96 projects toward the second engagement section 105 by dint of the force of the insert molded magnet of the first accommodation section 107. In this state, the first engagement section 95 and the second engagement section 105 are out of engagement with each other.

When the second housing 30 is rotated in this state toward the vertical orientation around the second rotary shaft 42, the second accommodation section 108 rotates as one with the second housing 30, whereupon the second projection 102 of the engagement pawl 96 is caught by the opening 108a. Specifically, the first engagement section 95 and the second engagement section 105 come into engagement with each other.

Herewith, the first engagement section 95 of the first housing 20 and the second engagement section 105 of the second housing 30 are out of engagement with each other in the closed state. Therefore, the second housing is not obstructed when opened in the closed state toward the vertical orientation around the first rotary shaft 41.

Further, on the occasion of the second housing being opened in the closed state toward the horizontal orientation around the second rotary shaft 42, the first engagement section 95 and the second engagement section 105 come into engagement with each other when the second housing 30 starts rotating around the second rotary shaft 42, to thus yield sufficient strength. Thus, the portable terminal can be stably opened in the horizontal orientation.

The portable terminal 10 of the first embodiment is configured as follows: Namely, when the portable terminal is in a closed state, the surface 43a of the joint 40 continually lies in level with the operation surface 20a of the first housing 20. Further, the surface 43a of the joint 40 opposes the display surface 30a of the second housing 30. When the portable terminal is opened in the vertical orientation, the joint 40 makes a rotation with the surface 43a of the joint 40 stayed opposite the display surface 30a of the second housing 30. Further, the surface 43a of the joint 40 and the operation surface 20a of the first housing 20 are oriented in mutually different directions. When the portable terminal is opened in the horizontal orientation, the surface 43a of the joint 40 continually lies in level with the operation surface 20a of the first housing 20. Further, the surface 43a of the joint 40 and the display surface 30a of the second housing 30 are oriented in mutually different directions.

As above, in the rotary apparatus 45 of the first embodiment, the first sleeve 68 and the second sleeve 69 are spaced apart from each other as shown in FIG. 12(A). Therefore, a distance L2 between the most distal ends of the first sleeve 68 and the second sleeve 69 can be made greater than a sum of an entire length L3 of the first sleeve 68 and an entire length L4 of the second sleeve 69.

In the rotary apparatus 45 of the present invention, even when external forces are exerted on the shaft member as designated by the arrow in such a way that the axial line of the first sleeve 68, the axial line of the second sleeve 69, and the axial line of the shaft member 87 become inclined with respect to each other, inclinations existing among the axial line of the first sleeve 68, the axial line of the second sleeve 69, and the axial line of the shaft member 87 can be diminished, thereby making rattles, or the like, difficult to occur.

In the meantime, in a case where there is adopted one sleeve 110 whose entire length L1 is equivalent to a sum of the entire length L3 of the first sleeve 68 and the entire length L4 of the second sleeve 69 as shown in FIG. 12(B), when external forces are exerted, as designated by the arrow, on the shaft member in such a way that an axial line of the sleeve 110 and the axial line of the shaft member 87 become inclined with respect to each other, it is difficult to suppress the inclinations existing between the axial line of the sleeve 110 and the axial line of the shaft member 87, which in turn makes it easy to cause rattles, or the like.

In particular, miniaturization of the joint has recently been demanded along with miniaturization of the portable electronic devices. As shown in FIG. 12(C), a conceivable measure to meet such a demand is to reduce the entire length L1 of a sleeve 111.

However, in a case where the sleeve 111 is shortened, when external forces, which would impose inclinations in the axial line of the sleeve 111 and the axial line of the shaft member 87, are exerted as designated by the arrow on the shaft member, the power of the sleeve 111 for supporting the shaft 87 is low, and rattles become much easier to arise.

Moreover, when the rotary apparatus 45 of the present invention can allow occurrence of rattles equivalent to those occurred in the related rotary apparatus, the thickness and entire length of either or both of the first sleeve 68 and the second sleeve 69 can be made smaller than the thickness and entire length of their counterparts in the related rotary apparatus. Consequently, the entire shape of the rotary apparatus can be made smaller.

Furthermore, in the rotary apparatus 45 of the present invention, the annular member 53 that rotates in synchronism with the shaft member 87 is provided with the pair of projections 57 of the relative angle maintenance unit 55. Hence, even the shaft member 87 rotates through any angle with respect to the first sleeve 68 as a result of the positions of the pair of projections 57 being selected as required, the relative angle can be retained.

Accordingly, in the rotary apparatus 45 of the present invention, the first member 51 is secured to the joint 40 of the portable terminal 10, and the second member 52 is secured to the second housing 30 of the same. So long as settings are previously made in such a way that the projections 57 come into engagement with the first recesses 75 or the second recesses 76 when the portable terminal 10 is in the closed state or the horizontal open state, when the portable terminal shifts from the closed state to the horizontal open state or when the portable terminal shifts from the horizontal open state to the closed state, the projections 57 come into engagement with the first recesses 75 and the second recesses 76 or the projections 57 come out of engagement of the first recesses 75 and the second recesses 76, whereby the user comes to feel superior usage sense.

In particular, so long as the degree of biasing pressure applied by the biasing member 54 and the depth of engagement of the first recesses 75, the second recesses 76, and the projections 57 are selected as required, the rotary apparatus 45 of the present invention enables arbitrary setting of the intensity, hardness, or the like, of the click feeling. Further, even when the portable terminal is situated at a position between the foregoing closed state and the foregoing horizontal open state, the projections 57 make sliding contact with respect to the first end face 68a of the first sleeve 68; hence, given torque is generated.

In the rotary apparatus 45 of the present invention, the biasing pressure is set to a preset value by means of the insertion maintenance unit 56 that brings the C ring member 96 into an engagement with the circumferential slit 91 of the shaft member 87 at a position between the second sleeve 69 and the biasing member 54. Put another way, the biasing pressure does not develop before the C ring member 96 is brought into engagement with the circumferential slit 91.

Therefore, in relation to the rotary apparatus 45 of the present invention, it becomes possible to easily perform assembly operation for inserting the shaft member 87 into the first sleeve 68, the second sleeve 69, the annular member 53, and the biasing member 54. Further, it also becomes possible to easily disassemble the rotary apparatus by removing the C ring member 96 from the circumferential slit 91.

In particular, during disassembly of the rotary apparatus 45 of the present invention, there is no necessity to perform destructive disassembly which would be performed when a specific part is subjected to; for instance, caulking, welding, bonding, press-fitting, or the like. Therefore, recycle of the respective parts during reassembly becomes possible. Further, separated disposal of the rotary apparatus performed on a per-material basis also becomes possible.

In addition, in the rotary apparatus 45 of the present invention, the C ring member 96 is brought, as the insertion maintenance unit 56, into engagement with the circumferential slit 91 of the shaft member 87. Therefore, for instance, when compared with the case where the C ring member 96 is brought into engagement with the circumferential slit 91 at an end 87b (see FIG. 6) of the shaft member 87, the distance L2 [see FIG. 5 and FIG. 12(A)] between the most distal ends of the first sleeve 68 and the second sleeve 69 can be made greater. As a result, the advantage of the ability to lessen the inclinations existing among the axial line of the first sleeve 68, the axial line of the second sleeve 69, and the axial line of the shaft member 87 is further enhanced.

In the rotary apparatus 45 of the present invention, biasing pressure develops as a result of the C ring member 96 being brought into engagement with the circumferential slit 91. Hence, biasing pressure can be arbitrarily set by means of selecting the axial dimension of the C ring member 96 as required. Even after the rotary apparatus has been assembled, biasing pressure can be changed by selective use of the C ring member 96 having a different axial dimension.

Further, in the rotary apparatus 45 of the present invention, the first sleeve 68 and the second sleeve 69 are formed as one by way of the housing fix portion 71. Hence, the distance L2 between the first sleeve 68 and the second sleeve 69 [see FIG. 5 and FIG. 12(A)] can be retained without fail.

Specifically, in the rotary apparatus 45 of the present invention, the distance L between the first sleeve 68 and the second sleeve 69 can be retained so as to be exactly equal to a design value. Therefore, the annular end face 53b of the annular member 53 is forcefully actuated toward the first end face 68a of the first sleeve 68 by dint of desired biasing pressure. Click feeling and torque stemming from rotating action are thereby enhanced, and operation accuracy can be made uniform at a high level without involvement of occurrence of an individual difference.

Further, in the rotary apparatus 45 of the present invention, the first sleeve 68 and the second sleeve 69 are formed as one by way of the housing fix portion 71. Consequently, when the rotary apparatus is used as the joint 40 of the portable terminal 10, the joint can be built in an easier manner when compared with a case where the first sleeve 68 and the second sleeve 69 are separate members.

In addition, in the rotary apparatus 45 of the present invention, the second sleeve contact surface 78 and the shaft member contact surface 94 come into plane contact with each other, whereby the rotation angles of the first member 51 and the second member 52 are regulated. Therefore, in other words, the rotary regulation unit 58 is provided around the second rotary shaft 42 (the shaft member 87). Accordingly, rotating action of the second rotary shaft can be directly regulated without fail.

In the rotary apparatus 45 of the present invention, the projecting member 62 and the shaft member contact surface 94 are brought into plane contact with each other, thereby regulating relative rotating actions of the first member 51 and the second member 52 around the axial line of the shaft member 87. For this reason, when the rotary apparatus is adopted as a horizontal-open rotary apparatus 45 in the joint 40 of the portable terminal 10 that can assume; for instance, both a vertical open state and a horizontal open state, the portable terminal in the vertical open state can be reliably prevented from coming into a horizontal open state, so long as settings are previously made such that the projecting member 62 projects from the second sleeve 69 when the portable terminal starts shifting from the closed state to the vertical open state.

Further, in the rotary apparatus 45 of the present invention, the projecting member 62 projects from the second sleeve 69 by means of the elastic member 64 as required. Therefore, relative rotations of the first member 51 and the second member 52 around the axial line of the shaft member 87 can be reliably regulated.

In addition, in the rotary apparatus 45 of the present invention, the sloped contact surface 62a that comes into plane contact with the shaft member contact surface 94 is provided at a leading end of the projecting member 62. Put another way, when compared with the case where the shaft member contact surface 94 and the sloped contact surface 62a are orthogonal to the circumferential direction of the second sleeve 69 and the shaft member 87, the shaft member contact surface 94 and the sloped contact surface 62a come into plane contact with each other as shown in FIG. 8(D), whereby the second sleeve 69 and the shaft member 87 are pressed so as to rotate relatively to each other in opposite directions along the circumference.

Specifically, in the rotary apparatus 45 of the present invention, not only occurrence of relative rotations between the second sleeve 69 and the shaft member 87 is regulated. In addition, the shaft member contact surface 94 and the sloped contact surface 62a come into plane contact with each other as if they were wedged to each other, whereby the relative position between the second sleeve 69 and the shaft member 87 can be retained without involvement of rattles therebetween.

Incidentally, consideration is given to a case where the rotary apparatus 45 of the present invention is adopted as; for instance, a horizontal-oriented open rotary apparatus 45 in the joint 40 of the portable terminal 10 capable of assuming both the vertical open state and the horizontal open state. Consideration is also given to a case where the projecting member 62 is set so as not to project from the second sleeve 69 in the closed state of the portable terminal but to project from the second sleeve 69 when the portable terminal starts shifting from the closed state to the vertical open state. Under the circumstance, the following may happen if an upright plane orthogonal to the circumferential direction of the shaft member 87 is formed on the opposite side of the location of the shaft member contact surface 94.

Specifically, the user is assumed to perform operation departed from the original use mode; namely, operation for rotating the upper housing around the rotary shaft for vertical-oriented opening with respect to the lower housing after having shifted the portable terminal 10 from the closed state to the horizontal open state, whereby the portable terminal is brought into an incomplete horizontal open state. In such a case, when the portable terminal starts shifting from the horizontal open state to the incomplete vertical open state, the projecting member 62 projects from the second sleeve 69 as shown in FIG. 8(A).

Accordingly, in such a portable terminal 10, the upright surface interferes with the projecting member 62, so that the second sleeve 69 and the shaft member 87 cannot perform relative rotations. As a result, the portable terminal may not be able to return from the incomplete vertical open state to the normal vertical open state.

In contrast, as shown in FIG. 8(A), the rotary apparatus 45 of the present invention is configured so as to have the return inclined surface 66 that intersects with the circumferential direction of the shaft member 87 and that is provided on the opposite side of the location of the shaft member contact surface 94.

With such a configuration, the rotary apparatus 45 of the present invention will perform the following conceivable operation. Namely, after the second housing 30 of the portable terminal 10 has been opened in the horizontal orientation as designated by the arrow as shown in FIG. 13(A), the second housing 30 becomes incompletely opened, as designated by the arrow, in the vertical orientation around the first rotary shaft 41 for vertical-oriented opening with respect to the first housing 20 as shown in FIG. 13(B).

In this state, the second sleeve 69 and the shaft member 87 can perform relative rotations while the projecting member 62 is pushed into the second sleeve 69 by means of the return inclined surface 66.

As shown in FIG. 13(C), the second housing 30 can thereby be returned to the normal vertical open state from the incomplete vertical open state as designated by the arrow.

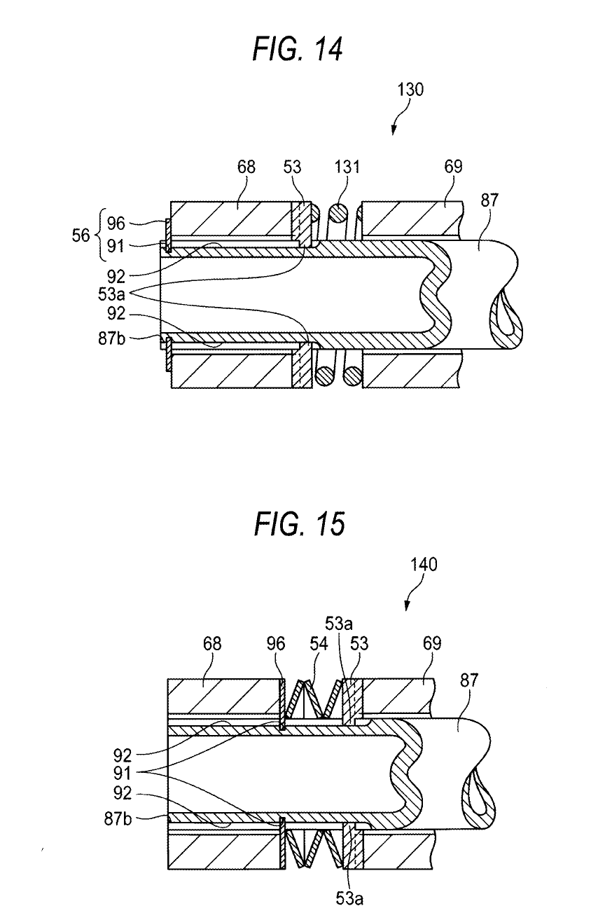

Next, portable terminals that are portable electronic devices of second to fourth embodiments of the present invention will be described by reference to FIGS. 14 to 16.

In the second through fourth embodiments which will be described below, elements common to the foregoing portable terminal 10 of the first embodiment are assigned like reference numerals, and their repeated explanations are omitted.

### Second Embodiment

FIG. 14 is a cross sectional view showing a biasing member provided in a portable terminal of a second embodiment.

As shown in FIG. 14, a portable terminal 130 of the second embodiment is provided with a biasing member 131 formed from a coil spring in place of the biasing member 54. The C ring member 96 is provided at the end 87b of the shaft member 87.

As above, so long as the biasing member 131 formed from a coil spring is used in the portable terminal 130 of the second embodiment, the number of parts can be reduced because force can be applied by use of one coil spring.

In place of the disc spring described in connection with the first embodiment and the coil spring described in connection with the second embodiment, a bamboo spring and a wave washer, for instance, can be exemplified as the biasing member. Further, the number of biasing members is arbitrary.

### Third Embodiment

FIG. 15 is a cross sectional view showing an annular member and a C ring member provided in a portable terminal of a third embodiment.

As shown in FIG. 15, in a portable terminal 140 of the third embodiment, the annular member 53 is disposed on the second sleeve 69, whilst the C ring member 96 is disposed on the first sleeve 68.

The portable electronic device of the present invention is not restricted to the portable terminals described in connection with the respective embodiments and susceptible to alterations, improvements, and the like, as required.

For instance, the first embodiment exemplifies the first recesses 75 with which the projections 57 come into engagement in the closed state of the portable terminal 10 and the second recesses with which the projections come into engagement with in the horizontal open state. However, it may also be possible to provide either the first recesses or the second recesses.

The first embodiment has mentioned about the example in which the pair of projections 57 of the relative angle maintenance unit 55 are provided on the annular member 53 and in which the first recesses 75 and the second recesses 76 are provided on the first sleeve 68. It is also possible to form the first recesses 75 and the second recesses 76 in the annular member 53 and the pair of projections 57 on the first sleeve 68.

The portable electronic device of the present invention is not restricted to the foregoing embodiments and susceptible to modifications, improvements, and the like, as required.

For instance, the present embodiment has exemplified the portable terminals as portable electronic devices. In addition, the present invention can also be applied to portable electronic devices, such as a PDA, a notebook personal computer, and a game machine.

The present patent application is based on Japanese Patent Applications (JP-2008-314445 and JP-2008-314446) filed on Dec. 10, 2008, the entire subject matters of which are incorporated herein by reference.

### INDUSTRIAL APPLICABILITY

The present invention is suitable for use with a portable electronic device, like a portable terminal.

### DESCRIPTIONS OF THE REFERENCE NUMERALS AND SYMBOLS

10, 130, 140 PORTABLE TERMINAL (PORTABLE ELECTRONIC DEVICE)
21 OPERATION SECTION
20 FIRST HOUSING
30 SECOND HOUSING
31 MAIN DISPLAY SECTION (DISPLAY SECTION)
35 SUB-DISPLAY SECTION (DISPLAY SECTION)
51 FIRST MEMBER
52 SECOND MEMBER
53 ANNULAR MEMBER
53b ANNULAR END FACE
54, 131 BIASING MEMBER
55 RELATIVE ANGLE MAINTENANCE UNIT
56 INSERTION MAINTENANCE UNIT
57 BUMP
58 ROTARY REGULATION UNIT
61 GUIDE SLIT
62 PROJECTING MEMBER
62a SLOPED CONTACT SURFACE
64 ELASTIC MEMBER
66 RETURN INCLINED SURFACE
68 FIRST SLEEVE
68a FIRST END FACE OF FIRST SLEEVE
69 SECOND SLEEVE
69a END OF SECOND SLEEVE
71 HOUSING SECURE PORTION
75 FIRST RECESS (RECESS)
76 SECOND RECESS (RECESS)
78 SECOND SLEEVE CONTACT SURFACE
87 SHAFT MEMBER
91 CIRCUMFERENTIAL SLIT
94 SHAFT MEMBER CONTACT SURFACE
96 C RING MEMBER

1. A rotary apparatus comprising:
a first member that has a first sleeve and a second sleeve which are spaced apart from each other;
a second member that has a shaft member which is inserted into both the first sleeve and the second sleeve and which is adapted to rotate axially with respect to the first sleeve and the second sleeve;
an annular member that faces a first end face of the first sleeve oriented to the second sleeve and that rotates with the shaft member;
a biasing member into which the shaft member is inserted at a position between the second sleeve and the annular member, and that biases the annular member toward the first end face of the first sleeve;
a relative angle maintenance unit that has a projection provided on one of the first sleeve and the annular member so as to project toward the other of the first sleeve and the annular member and a recess which is provided on the other of the first sleeve and the annular member to be engaged with the projection and that maintains the first sleeve and the shaft member at a predetermined angle by engagement of the projection with the recess; and
an insertion maintenance unit that maintains the inserted condition of the shaft member with respect to the first sleeve and the second sleeve.

2. The rotary apparatus according to claim 1, wherein the insertion maintenance unit has a circumferential slit, which is formed in a circumferential direction at a position on a peripheral surface of the shaft member corresponding to a space between the second sleeve and the biasing member, and a ring member having a substantially C shape to be engaged with the slit; and
wherein a biasing pressure that biases the annular member toward the first end face of the first sleeve comes to a preset value when the ring member engages with the circumferential slit.

3. The rotary apparatus according to claim 1, wherein the first sleeve and the second sleeve are integrally formed as one by an housing secure portion.

4. The rotary apparatus according to claim 1, further comprising:
a rotary regulation unit that includes:
a second sleeve contact surface which is provided on an end portion of the second sleeve on an opposite side of the first sleeve and which intersects with a circumferential direction of the second sleeve; and
a shaft member contact surface which is provided on the shaft member and which is adapted to contact in plane with the second sleeve contact surface; and
wherein the rotary regulation unit regulates rotation angles of the first member and the second member around an axial line of the shaft member by plane-contacting the second sleeve contact surface with the shaft member contact surface.

5. The rotary apparatus according to claim 1, further comprising:
a guide slit that is formed in the second sleeve along its longitudinal direction; and
a projecting member that is accommodated in the guide slit and that is adapted to project toward the shaft member,
wherein the shaft member contact surface which intersects with the circumferential direction of the shaft member is adapted to contact the projecting member.

6. The rotary apparatus according to claim 1, further comprising:
an elastic member that biases the projecting member toward the shaft member.

7. The rotary apparatus according to claim 1, wherein a leading end portion of the projecting member has a substantially plate shape extending in a radial direction of the sleeve, and has a sloped contact surface whose thickness continually becomes smaller along a projecting direction of the projecting member.

8. The rotary apparatus according to claim 1, wherein the shaft member has a return inclined surface which intersects with the circumferential direction of the shaft member and which is arranged at an opposite side of the shaft member contact surface.

9. A rotary apparatus comprising:
a first member that has a sleeve;
a second member that is inserted into the sleeve and that has a shaft member which is axially rotatable relatively to the sleeve;
a guide slit that is formed in the sleeve along its longitudinal direction;
a projecting member that is accommodated in the guide slit and that is adapted to project toward the shaft member; and
a shaft member contact surface that intersects with a circumferential direction of the shaft member and that is adapted to contact the projecting member.

10. The rotary apparatus according to claim 9, further comprising:
an elastic member that biases the projecting member toward the shaft member.

11. The rotary apparatus according to claim 9, wherein a leading end portion of the projecting member has a substantially plate shape extending in a radial direction of the sleeve and in a projecting direction of the projecting member, and has a sloped contact surface whose thickness continually becomes smaller along the projecting direction of the projecting member.

12. The rotary apparatus according to claim 9, further comprising:
a return inclined surface that intersects with the circumferential direction of the shaft member and that is arranged at an opposite side of the shaft member contact surface.

13. A portable electronic device comprising:
a first housing that has an operation section;
a second housing that has a display section;
a joint housing for joining the first housing and the second housing together;
an operation surface provided with the operation section in order to join the first housing to the joint housing;
a first joint shaft provided between the operation surface and a surface of the first housing on the other side of the operation surface; and
a second joint shaft provided for joining the second housing and the joint housing together,
wherein a surface of the joint housing continually lies in level with the operation surface of the first housing and also opposes a display surface in which the display section of the second housing is provided when the first housing and the second housing are stacked on top of each other in a closed state;
wherein, in a vertical open state where the first housing and the second housing are relatively rotatable around the first joint shaft from the closed state, the joint housing rotates while the surface of the joint housing opposes the display surface of the second housing, and the surface of the joint housing and the operation surface are oriented in mutually different directions;
wherein, in a horizontal open state where the first housing and the second housing are relatively rotatable around the second joint shaft from the closed state, the surface of the joint housing continually lies in level with the operation surface of the first housing, and the surface of the joint housing and the display surface of the second housing are oriented in mutually different directions;
wherein the second joint shaft is equipped with the rotary apparatus according to claim 1;
wherein the first member of the rotary apparatus is secured to the joint housing;
wherein the second member of the rotary apparatus is secured to the second housing; and
wherein the first housing is provided with a lock section for controlling engagement of the projecting member with the shaft member.

14. A portable electronic device comprising:
a first housing that has an operation section;
a second housing that has a display section;
a joint housing for joining the first housing and the second housing together;
an operation surface provided with the operation section in order to join the first housing to the joint housing;
a first joint shaft provided between the operation surface and a surface of the first housing on the other side of the operation surface; and
a second joint shaft provided for joining the second housing and the joint housing together,
wherein a surface of the joint housing continually lies in level with the operation surface of the first housing and also opposes a display surface in which the display section of the second housing is provided when the first housing and the second housing are stacked on top of each other in a closed state;
wherein, in a vertical open state where the first housing and the second housing are relatively rotatable around the first joint shaft from the closed state, the joint housing rotates while the surface of the joint housing opposes the display surface of the second housing, and the surface of the joint housing and the operation surface are oriented in mutually different directions;
wherein, in a horizontal open state where the first housing and the second housing are relatively rotatable around the second joint shaft from the closed state, the surface of the joint housing continually lies in level with the operation surface of the first housing, and the surface of the joint housing and the display surface of the second housing are oriented in mutually different directions;
wherein the second joint shaft is equipped with the rotary apparatus according to claim 9;
wherein the first member of the rotary apparatus is secured to the joint housing;
wherein the second member of the rotary apparatus is secured to the second housing; and
wherein the first housing is provided with a lock section for controlling engagement of the projecting member with the shaft member.
